(19) United States
(12) Patent Application Publication
(10) Pub. No.: US 2001/0015443 A1
(43) Pub. Date: Aug. 23, 2001

(54) SEMICONDUCTOR LIGHT EMITTING DEVICE

(76) Inventor: SATOSHI KOMOTO, SUGINAMI-KU (JP)

Correspondence Address: WILLIAM H. WRIGHT, ESQ., HOGAN & HARTSON, L.L.P., BILTMORE TOWER, 500 SOUTH GRAND AVENUE, SUITE 1900, LOS ANGELES, CA, 90071, US

(21) Appl. No.: 09/320,379

(22) Filed: May 26, 1999

(30) Foreign Application Priority Data
May 27, 1998 (JP) 145824/1998

(51) Int. Cl. H01L 27/15; H01L 31/12; H01L 33/00

(52) U.S. Cl. 257/81

(57) ABSTRACT

A semiconductor light emitting device includes a lead frame made of a material having a thermal conductivity not higher than 100 W/(m·K), and a gallium nitride compound semiconductor light emitting element mounted on the lead frame. Alternatively, the semiconductor light emitting device includes a lead frame, a gallium nitride compound semiconductor light emitting element mounted on the lead frame, wires connecting electrode terminals of the lead frame to the light emitting element, a first encapsulater provided around the light emitting element to cover it, and a second encapsulater provided around the first encapsulater to cover it. Each wire has a larger diameter at one end portion thereof connected to the light emitting element than that of its major part, and the first encapsulater is provided so that its surface extends across the end portions.

### BACKGROUND OF THE INVENTION

This invention relates to a semiconductor light emitting device and, more particularly, to a light emitting device incorporating a gallium nitride compound semiconductor light emitting element, which is remarkably improved in heat resistance to soldering and in reliability.

Semiconductor light emitting devices have many advantages such as compactness, low power consumption and high reliability, and are widely expanding their field of application to indoor/outdoor displays, railway/traffic signals, compartment/cabin lamps, and so on.

Among these semiconductor light emitting devices, those using gallium nitride compound semiconductors are especially remarked. Gallium nitride semiconductors are direct transition type III-V compound semiconductors, and they ensure highly efficient emission of light in relatively short wavelength bands.

In the present application, the term “gallium nitride compound semiconductor” pertains to any III-V compound semiconductor expressed by BₓIN_{y}Al_{z}Ga_{(1-x-y-z)}N (0≧x≧1, 0≧y≧1, 0≧z≧1, 0≧x+y+z≧1), and group V elements are construed to also involve mixed crystals containing phosphorus (P) and/or arsenic (As) in addition to N. For example, InGaN (x=0 y=0.3, z=0) is also involved in “gallium nitride compound semiconductors”.

Additionally, “gallium nitride compound semiconductor light emitting elements” are semiconductor light emitting elements including “gallium nitride compound semiconductors” in their light emitting layers, and involve various types of light emitting elements like LEDs (light emitting diodes) and semiconductor lasers.

Because gallium nitride compound semiconductors can be largely change in band gap by controlling their mole fractions x, y and z, they are regarded as hopeful materials of LEDs and semiconductor lasers. Especially, if highly luminous emission is realized in blue and ultraviolet wavelength bands, recording capacity of various optical discs can be doubled.

Moreover, if a fluorescent material is excited by using such short wavelength light, a light source with a remarkably high freedom in emission wavelength can be realized. That is, it will be possible to select any emission wavelength from a wide wavelength region from visible light to infrared light, and full-color displays will be readily realized.

Under these circumstances, improvements of initial property and reliability are an urgent issue regarding gallium nitride compound semiconductor light emitting element using gallium nitride compound semiconductors as their light emitting layers.

### SUMMARY OF THE INVENTION

It is therefore an object of the invention to provide a gallium nitride compound semiconductor light emitting device having a high heat resistance and stable upon soldering in its packaging process.

According to the invention, there is provided a semiconductor light emitting device comprising a lead frame and a gallium nitride compound semiconductor light emitting element mounted on the lead frame, and characterized in that the lead frame is made of a material having a thermal conductivity not higher than 100 W/(m·K).

According to the invention, there is further provided a semiconductor light emitting device comprising a lead frame, a gallium nitride compound semiconductor light emitting element mounted on the lead frame, a wire connecting an electrode terminal of the lead frame to the light emitting element, a first encapsulater provided around the light emitting element to cover it, and a second encapsulater provided around the first encapsulater to cover it, and characterized in that the wire has a larger diameter at one end portion thereof connected to the light emitting element than the remainder part thereof, and the boundary between the first encapsulater and the second encapsulater extends across this end portion.

The coefficient of linear expansion of said first encapsulater preferably lie between that of said second encapsulater and said that of said a gallium nitride compound semiconductor light emitting element.

The first encapsulater may contain a fluorescent material to absorb light of a first wavelength emitted from said light emitting element and to emit light of a second wavelength different from said first wavelength.

The first encapsulater may be made of an inorganic adhesive.

The inorganic adhesive is preferably made of any one selected from the group consisting of alkali metal silicate, phosphate, colloidal silica, silica sol, water glass, Si(OH)ₙ, SiO₂ and TiO₂.

The second encapsulater may be made of a material having a glass transition temperature not lower than 150° C.

The second encapsulater may be made of epoxy resin.

The lead frame is preferably made of an iron-based material.

The lead frame may have an outer lead portion applied with solder outer plating.

The invention is embodied in the above-explained modes, and attains the following effects.

Since the lead frame is made of a material having a thermal conductivity not larger than 100 W/ (mK), heat resistance against soldering is remarkably improved.

When the wires include large-diameter portions, and the encapsulater covering the semiconductor light emitting element is configured so that is surface extends across the large-diameter portions of the wires, the invention promises significant decrease of breakage of the wires, and remarkably improves the production yield and the reliability of the semiconductor light emitting device.

Additionally, by making a cup portion in the lead frame and roughly finishing at least a part of its inner wall surface, the invention can improve the affinity of the lead frame to the encapsulater to prevent a loss of optical reflection due to peeling along the interface.

When a fluorescent material is mixed into the encapsulater by a high density, conventional devices often became less resistive to heat due to changes in thermal expansion coefficient of the encapsulater as the matrix. According to the invention, however, taking the above-explained measures when mixing a fluorescent material into the encapsulater and the adhesive, problems about heat resistance and external quantum efficiency can be overcome.

Furthermore, according to the invention, by using an inorganic adhesive as the encapsulater covering the light emitting element, heat resistance of the encapsulater can be increased relative to its setting temperature, and it can be hardened in a relatively short time. That is, the encapsulater sets at a heating process at approximately 100 through 150° C. which is approximately equal to the temperature for a conventional resin encapsulating process, and a post-setting heat resistance as high as approximately 200 through 1000° C. can be realized. The setting time is also as relatively short as 20 through 30 minutes, approximately. Additionally, since its volume contracts due to vaporization of moisture upon setting, a thin film of the contained fluorescent material can be made on the semiconductor light emitting element 14 or on the inner wall surface of the cup portion. Further, since its viscosity is low enough for the fluorescent material to precipitate easily upon setting, a thin layer of the fluorescent material can be made.

Additionally, the invention remarkably improves the heat resistance against soldering by the use of an iron-based lead frame.

The invention also facilitates packaging by soldering to a board, for example, by enabling outer plating of solder onto the outer lead portion, which was impossible conventionally. Moreover, since the exposed cut end can be protected by the outer plating, the problem of corrosion of the matrix (especially of iron) from the cut end can be prevented.

Furthermore, the invention remarkably improves the heat resistance to soldering by setting the glass transition temperature of the encapsulater higher than 150° C.

As described above, the invention realized a semiconductor light emitting device with a high heat resistance against soldering and a high reliability, and its industrial merit is great.

### BRIEF DESCRIPTION OF THE DRAWINGS

The present invention will be understood more fully from the detailed description given herebelow and from the accompanying drawings of the preferred embodiments of the invention. However, the drawings are not intended to imply limitation of the invention to a specific embodiment, but are for explanation and understanding only.

In the drawings:

FIGS. 1A and 1B are cross-sectional views schematically showing construction of a gallium nitride compound semiconductor light emitting device according to the invention, in which FIG. 1A shows its entirety and FIG. 1B shows its central part;

FIGS. 2A and 2B are cross-sectional views schematically showing construction of a semiconductor light emitting element taken as a comparative sample, in which FIG. 2A shows its entirety and FIG. 2B shows its central part;

FIG. 3 is a graph showing relations between durations of soldering time and temperatures around light emitting elements;

FIGS. 4A and 4B are cross-sectional views schematically showing construction of another semiconductor light emitting device according to the invention, in which FIG. 4A shows its entirety, and FIG. 4B shows its central part; and

FIGS. 5A and 5B are cross-sectional views showing construction of a modified version of the semiconductor light emitting element shown in FIG. 4. in which FIG. 5A shows its entirety and FIG. 5B shows its central part.

### DETAILED DESCRIPTION OF THE PREFERRED EMBODIMENTS

The present invention uses as the material of the lead frame a material with a low thermal conductivity instead of those such as copper with a high thermal conductivity. Examples of this material are iron-based materials containing iron as their major component. These materials prevent overheating encapsulaters during soldering in the packaging and/or assembling processes of elements, and hence prevent wire breakage or other troubles. Moreover, the invention can remarkably reduce wire breakage by positionally adjusting the boundary between a first encapsulater and a second encapsulater.

Explained below are embodiments of the invention with reference to the drawings.

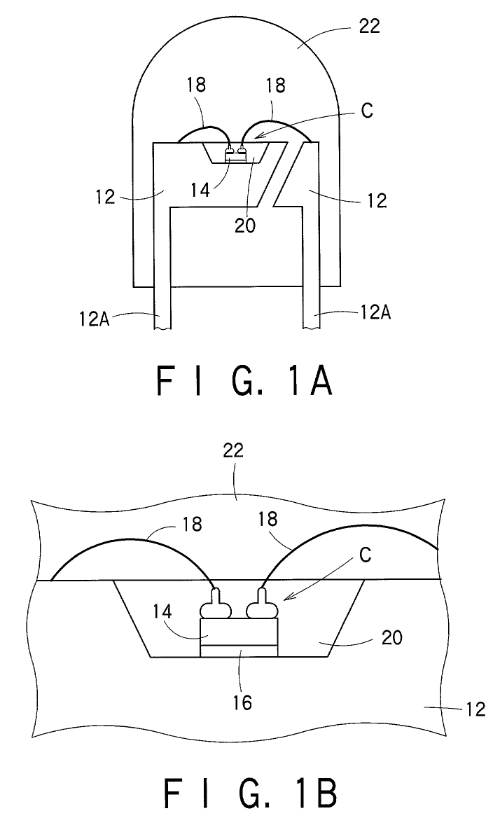

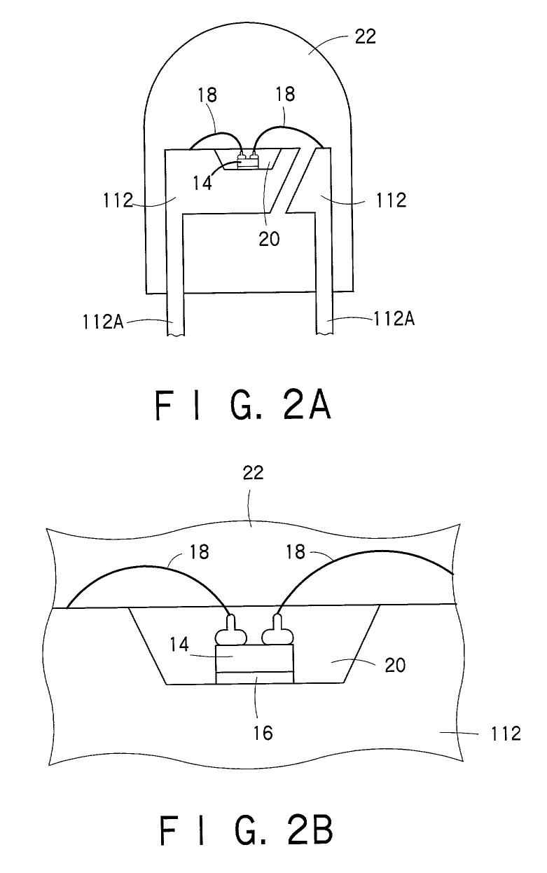

FIGS. 1A and 1B are cross-sectional views schematically showing construction of a gallium nitride compound semiconductor light emitting device according to the invention. FIG. 1A shows its entirety, and FIG. 2A shows its central part.

The semiconductor light emitting element according to the invention uses a lead frame 12 made of a material with a low thermal conductivity. Usable materials of the lead frame 12 are iron and iron-based alloys such as so-called “42 alloy”. The lead frame 12 includes a cup portion C in form of a recess. A gallium nitride compound semiconductor light emitting element 14 is mounted in the cup portion C. An adhesive 16, for example, may be used to mount the light emitting element 14. Preferably used as material of the adhesive 16 is an inorganic material having a heat resistance high enough to resist the heat applied in the wire bonding process. The adhesive 16 may contain a predetermined fluorescent material.

Electrodes, not shown, are provided on the light emitting element 14, and connected to the lead frame 12 by wires 18, 18, respectively. Usable as material of the wires is gold (Au) or aluminum (Al). The wires preferably have a diameter not smaller than 30 μm to ensure a mechanical strength against a stress. The cup portion C of the lead frame 12 is plugged with a first encapsulater 20 which covers the light emitting element 14. Epoxy resin or silicone resin is typically used as the first encapsulater 20. The first encapsulater 20 may contain a fluorescent material so that short wavelength light from the gallium nitride compound semiconductor light emitting element 14 be wavelength-converted and extracted as light with a predetermined wavelength. Alternatively, the first encapsulater 20 may contain a scattering agent.

Fluorescent materials efficiently excited by ultraviolet light are, for example, Y₂O₂S:Eu or La₂O₂S:Eu for emission of red light, (Sr, Ca, Ba, Eu)₁₀(PO₄)₆.Cl₂ for emission of blue light, and 3(Ba, Mg, Eu, Mn)O.8Al₂O₃ for emission of green light. If these fluorescent materials are mixed by an appropriate ratio, almost all colors in the visible band can be expressed.

Fluorescent materials which convert received light in the blue wavelength band into light with a longer wavelength involve organic fluorescent materials in addition to the above-introduced inorganic fluorescent materials. Appropriate organic fluorescent materials are, for example, rhodamine B for emission of red light and brilliant sulfoflavine FF for emission of green light.

The entirety of a head portion of the lead frame 12 protects the light emitting element 14 encapsulated by a second encapsulater 22, which may collect and spread light. Epoxy resin is typically used as the second encapsulater 22.

The “double-mold structure” using both the first encapsulater 20 and the second encapsulater 22 is particularly important for a semiconductor light emitting device using a fluorescent material. That is, in order to ensure that light emitted from the semiconductor light emitting element 14 be wavelength-converted, condensed and externally emitted with a high efficiency, it is desirable to provide a fluorescent material of a high density around the light emitting element 14. With reference to FIGS. 1A and 1B, if the fluorescent material is mixed also in the second encapsulater 22, then the emission source of light spread over the entire resin portion, and the function as a lens for condensing light will not be obtained. Therefore, in the “double-mold structure shown in FIGS. 1A and 1B, it is important to mix a fluorescent material merely in the first encapsulater 20 around the light emitting element 14.

The semiconductor light emitting device with the “double-mold structure” ensures that the fluorescent material contained in the first encapsulater 20 converts the wavelength of short wavelength light emitted from the light emitting element 14 and the second encapsulater 22 converges or spreads the light to be externally guided.

On the other hand, solder plating is applied onto an outer lead portion 12A of the lead frame 12 to facilitate soldering in the assembling process of the element.

Next explained is general construction of a semiconductor light emitting device prepared as a comparative sample by the Inventor in the course of his researches toward the present invention.

FIGS. 2A and 2B are cross-sectional views schematically showing construction of the semiconductor light emitting device as the comparative sample. FIG. 2A shows its entirety, and FIG. 2B shows its central part. In these drawings, the same components as those in FIGS. 1A and 1B are labeled with common reference numerals, and their detailed explanation is omitted.

The semiconductor light emitting device shown here as the comparative sample is clearly different from the semiconductor light emitting device according to the invention shown in FIGS. 1A and 1B in respect of using a lead frame 112 made of a material with a high thermal conductivity, such as deoxidized copper phosphate or other copper material, as explained later in greater detail.

For practical use of a semiconductor light emitting device as shown in FIGS. 1A and 1B or FIGS. 2A and 2B, it must be assembled on a predetermined substrate or a socket by soldering an outer lead portion 12A or 112A of the lead frame 12 or 112.

However, as a result of tests and researches by the Inventor, it has been noted that the semiconductor light emitting device shown in FIGS. 2A and 2B as a comparative sample is insufficient in heat resistance and it is subject to various troubles caused by soldering upon assembling. More specifically, breakage of wires 18, decrease of external quantum efficiency and other troubles occurred due to soldering upon assembling. Further investigation was made to locate reasons of these troubles, and it was confirmed to be one of reasons that the encapsulaters 20 and 22 expanded when heated during soldering.

That is, it has been confirmed that the semiconductor light emitting device shown in FIGS. 2A and 2B as a comparative sample is liable to cause breakage of wires 18 due to expansion of the encapsulaters when heated upon soldering for assembling. Especially, a gallium nitride compound semiconductor light emitting element has two electrodes, namely, anode and cathode, on the surface of the element. Therefore, unlike a GaAs compound light emitting element, two wires 18 must be used in a single element. As a result, in case of a gallium nitride compound semiconductor light emitting device, the probability of wire breakage increases to twice that of a light emitting element using a single wire.

Moreover, the semiconductor light emitting devices shown in FIGS. 1A, 1B, 2A and 2B have a double-mold structure. The double-mold structure is a very convenient structure in order to contain a fluorescent material by a high density merely in the first encapsulater 20 around the light emitting element 14. However, in case that the first encapsulater 20 and the second encapsulater are different in thermal expansion coefficient, two encapsulaters expand with different expansion coefficients when heated upon soldering. Then, a large shearing stress is applied to wires 18 along the interface between these encapsulaters and causes breakage of wires.

Furthermore, it has been found extremely difficult to apply solder plating onto the outer lead portion 112A after encapsulation in the semiconductor light emitting device as the comparative sample because of its problem about heat resistance. Therefore, it is necessary to use a lead frame previously plated with silver as an alternative means. Nevertheless, solder plating cannot be applied onto the outer lead portion. As a result, in the soldering process for packaging, affinity of the solder is not sufficient, and the production yield decreases.

The semiconductor light emitting device according to the invention as shown in FIGS. 1A and 1B is much more advantageous in view of these problems.

The lead frame 12 used in the semiconductor light emitting device according to the invention is explained below in detail, comparing with the comparative sample. Iron-based material used as the material of the lead frame 12 has a much lower thermal conductivity than a copper-based material used to make the lead frame in the light emitting device shown in FIGS. 2A and 2B as the comparative sample.

Shown below are examples of copper-based materials and iron-based materials together with their heat conductivities.

| | | Conductivity |
|---|---|---|
| Materials | Heat | (W/m · K) |
| deoxidized copper phosphate | 400 | |
| KLF-1 | 220 | |
| iron (purity of 99% or more) | | 40 |
| 42 alloy | 16 | |

“KLF-1” is a product name of a copper (Cu) alloy (Kobe Steel Co., Ltd.) which contains approximately 0.3% of nickel (Ni) and approximately 0.7% of silicon (Si). “42 alloy” is a name of an iron (Fe) alloy containing approximately 42% of nickel. It is noted from the above-introduced data that copper-based “KLF-1” has a thermal conductivity as high as 10 times that of iron-based “42 alloy”.

Therefore, by using an iron-based lead frame made of iron or “42 alloy” in the present invention, heat applied to the outer lead portion upon soldering is not transmitted so much to the encapsulaters, and breakage of wires and decrease of the external quantum efficiency do not occur.

The Inventor made a review on heat characteristics of semiconductor light emitting devices according to the invention as shown in FIGS. 1A and 1B and semiconductor light emitting devices as comparative examples shown in FIGS. 2A and 2B upon soldering of their outer lead portions.

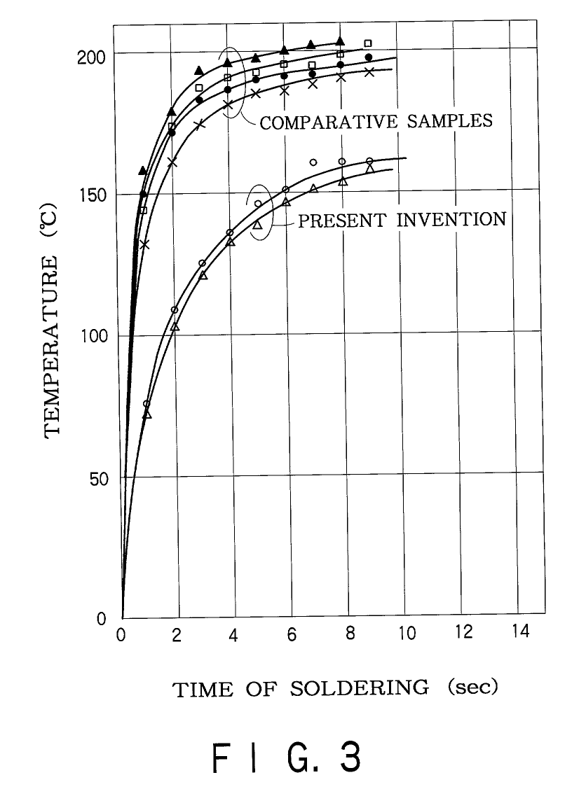

FIG. 3 is a graph showing relations between durations of time of soldering and temperatures of light emitting elements. That is, rising temperatures were measured in light emitting elements mounted on lead frames by the soldering process. In FIG. 3, the label “present invention” is attached to curves of semiconductor light emitting devices using iron-based lead frames whereas the label “comparative sample” is attached to curves of semiconductor light emitting devices using copper-based lead frames. Lead frames used here are press frames having the thickness of 0.5 mm, and they are equal in dimension in both the “present invention” and the “comparative sample”.

The time usually required for soldering or solder plating of the outer lead portion is approximately 5 seconds in maximum. It is noted from FIG. 3 that, in the “comparative samples”, temperature increases to 170° C. through 200° C. around the light emitting element during soldering for five seconds. In contrast, in case of the “present invention” using an iron-based lead frame, the maximum temperature of the light emitting element is limited to approximately 145° According to the invention, as a result of restricting the rise of temperature, the invention successfully suppresses thermal expansion of encapsulaters and prevents breakage of wires and a decrease of the external quantum efficiency.

The present invention is particularly effective when used in a light emitting device using a gallium nitride compound semiconductor and a fluorescent material. That is, light emitting devices of this type need a double-mold structure to provide a fluorescent material around the light emitting element with a high density. In a double-mold structure, however, a difference in thermal expansion coefficient between the inner mold and the outer mold often causes breakage of wires and peeling of a resin along their interface.

In contrast, the invention can prevent overheat of encapsulaters even in the double-mold structure, and therefore removes the problem of a decrease of the external quantum efficiency caused by breakage of wires or peeling of resins, among others.

Moreover, the invention successfully decreases the glass transition temperature of the encapsulaters 20 and 22 to 150° C. That is, as apparent from FIG. 3, the ambient temperature of the light emitting element can be limited to 150° C. or less even after soldering for approximately five seconds.

This means that materials having lower glass transition temperatures than conventionally acceptable materials can be used as the encapsulaters. Thus, the invention permits selection of encapsulaters from a wider range of materials, including those with smaller thermal expansion coefficients or residual stresses than those of conventionally acceptable materials.

Furthermore, according to the invention, solder plating can be applied onto the outer lead portion 12A without inviting any undesirable result of an increase in temperature. Therefore, it ensures stable soldering in the packaging process.

There is epoxy resin, which is an organic material widely used as the encapsulater. Its glass transition temperature is approximately 150° C. Therefore, it is preferable to ensure that the temperature never rises beyond 150° C. during the typical duration of soldering time, five seconds. For this purpose, a thermal conductivity not higher than 100 W/(mK) has been found desirable as the material of the lead frame as a result of calculation by the Inventor from the data shown in FIG. 3.

That is, by employing a material with a thermal conductivity not higher than 100 W/(mK) as the material of the lead frame, the present invention can realize a semiconductor light emitting device reduced in probability of malfunctions to an epoch-making level even through a soldering process.

Further effects listed below are additionally expected by employing an iron-based lead frame in the present invention.

That is, iron-based materials contribute to improving the optical reflectance as compared with copper-based materials. Especially in the wavelength bands from ultraviolet to blue emitted from gallium nitride compound semiconductor light emitting elements, optical reflectance can be improved, and the external quantum efficiency can be increased.

Additionally, the durability to a surge is high, and break-down or deterioration of the semiconductor light emitting element by the surge can be prevented.

In case of a copper-based material, copper in a main component may migrate and enter into the gallium nitride compound semiconductor, and may make a non-radiative recombination center to decrease the emission intensity. However, iron-based materials prevent such deterioration.

Furthermore, since an iron-based materials has a low susceptibility to high frequencies, adverse affection by high-frequency noise can be prevented.

Next made is detailed explanation on the first encapsulater 20 usable in the present invention.

As a result of tests and researches by the Inventor, inorganic adhesives have been found desirable as the first candidate of the first encapsulater 20. These inorganic adhesives contain an inorganic material like Si(OH)ₙ, SiO₂ or TiO₂ dispersed in mediums such as organic solvents, in which the inorganic material functions as the adhesive or plugging material when the medium dries or vaporized. Examples or inorganic adhesive materials are alkali metal silicate, phosphate, colloidal silica, silica sol and water glass. In addition to these, inorganic compounds such as Si(OH)ₙ, SiO₂ and TiO₂ are usable as the solute of the inorganic adhesive. Further usable are oxide compounds of aluminum (Al), tantalum (Ta), tin (Sn), germanium (Ge), tungsten (W), molybdenum (Mo), iron (Fe), chrome (Cr), zinc (Zn), cerium (Ce), cobalt (Co), magnesium (Mg), and so forth. Examples of these oxide compounds are aluminum oxide (Al₂O₃) and tantalum oxide (Ta₂O₅). Also usable are mixtures of these inorganic compounds.

Inorganic adhesive containing any of these inorganic compounds dispersed in a solvent is characterized in having a high heat resistance relative to its setting temperature and setting in a relatively short time. That is, it sets in a heating process under approximately 100 through 150° C. equivalent to a conventional resin encapsulating process, and a post-setting resistive temperature as high as approximately 200 through 1000° C. can be realized.

Heat resistance temperature means the one at which the bond, which was made during the process of hardening, among moleculars of the adhesive is cut and uncrosslinked, or chemically decomposed by the heat. Adhesive, whose heat resistance temperature is high, has a higher heat resistance. According to the invention, adhesive whose heat resistance temperature is not less than 150° C. is not decomposed and does not introduce decrease in its quality. Encapsulater having the heat resistance temperature not less than 150° C. and made of other than inorganic adhesive can also realize a heat resistance as high as that of inorganic adhesive.

The setting time is also as relatively short as approximately 20 through 30 minutes. Additionally, since its volume contracts upon setting due to vaporization of moisture, a thin layer of the fluorescent material contained therein can be made on the semiconductor light emitting element 14 or on the inner wall of the cup portion. Furthermore, since its viscosity is low, the fluorescent material readily precipitates upon setting, and the fluorescent layer can be made thin and even.

In comparison with these inorganic adhesives, the epoxy resin heretofore used as the first encapsulater was liable to cause breakage of wires because its linear expansion coefficient rapidly increases beyond the glass transition temperature. Additionally, in case of silicone resin, because its linear expansion coefficient is usually larger than that of the second encapsulater, peeling was liable to occur along its interface with the outer second encapsulater or lead frame upon heating. In contrast, any of inorganic adhesives used in the present invention has a relatively small linear expansion coefficient, and its volume is also relatively small because it is applied in form of a thin film. Therefore, its change in volume with temperature is relatively small, and those problems can be removed.

Both stresses on the interface between first encapsulater and second encapsulater, and stresses on the interface between second encapsulater and the GaN element can be reduced at minimum when coefficient of linear expansion of the first encapsulater, for example made of an inorganic adhesive, is determined at the value between that of the GaN element and that of the second encapsulater. Thus the peeling on the interface can be prevented.

In case of using an organic resin as the first encapsulater, a resin such as epoxy resin having a glass transition temperature of 150° C. or more is preferably used.

Next explained is a second semiconductor light emitting device according to the invention.

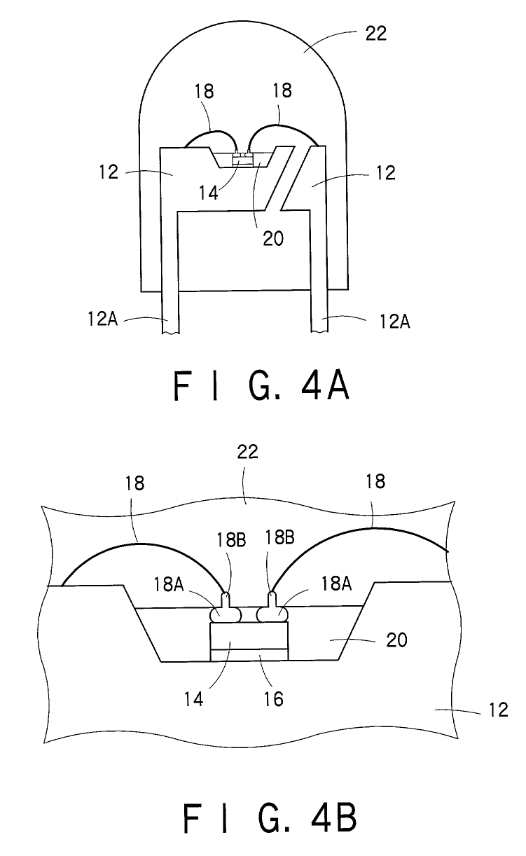

FIGS. 4a and 4B are cross-sectional views schematically showing construction of the second gallium nitride semiconductor light emitting device according to the invention. FIG. 4A shows its entirety, and FIG. 4B shows its central part. In these drawings, the same components as those explained with reference to FIGS. 1A and 1B are labeled with common reference numerals, and their detailed explanation is omitted.

In the example shown here, the interface between the first encapsulater 20 and the second encapsulater 22 extends across thick portions of wires, such as bonding ball portions or neck portions, as best shown in FIG. 4B. That is, when the wires 18 are bonded to the semiconductor light emitting element 14, ball portions 18A and neck portions 18B are formed at the connected portions.

Each ball portion 18A is first shaped as a ball by melting one of a wire before wire bonding and then flattened when pressed and connected to an electrode of the light emitting element 14 under application of an ultrasonic wave. Each neck portion 18B is a large-diameter portion made by one end of a capillary of a bonding apparatus having a larger inner diameter. Height of the ball portion 18A is approximately 50 through 100 μm in most cases. Length (height) of the neck portion 18B depends on the configuration of the open end of the capillary used for bonding, and it is typically decades to 100 μm approximately.

These large-diameter portions have higher mechanical strengths against shearing stress. Consequently, in case that these large-diameter portions in the wires 18 extend across the interface between the first encapsulater 20 and the second encapsulater 22, breakage of wires 18 can be prevented even when a shearing stress is applied along the interface between the encapsulaters due to a difference in thermal expansion coefficient between the first encapsulater 20 and the second encapsulater 22. Therefore, by using an inorganic coating material, a good thin film readily adjustable in amount to be plugged can be made because an inorganic coating material has a low viscosity.

Additionally, by appropriately selecting the shape of the capillary and bonding conditions to maximize diameters of the balls portions 18A and the neck portions 18B and to maximize their heights upon bonding these wires 18, breakage of the wires is prevented more effectively.

According to the invention, by controlling the level of the surface of the first encapsulater, a sufficient heat resistance is promised even in the double-mold structure.

Additionally, the first encapsulater 20 preferably has the same thermal expansion coefficient as that of the adhesive 16 used to mount the light emitting element 14. In this manner, application of useless stress to the light emitting element 14 can be prevented.

As an alternative example, although not shown, the first encapsulater resin 20 may be plugged to cover the entirety of the wires 18. When the wires are entirely covered with the first encapsulater 20, shearing stress, if any along the interface, is never applied to the wires 18.

On the other hand, epoxy resin, for example, may be used as the second encapsulater 22. Glass transition temperature of epoxy resin is approximately 150° C. Therefore, although the comparative sample of FIGS. 2A and 2B involves the problem that it is heated to a temperature far beyond the glass transition temperature upon soldering, the invention can perform soldering at a temperature not beyond the glass transition temperature.

Alternatively, if the second encapsulater is made of a material substantially equal to the first encapsulater 20 in thermal expansion coefficient instead of epoxy resin, shearing stress along the interface between them can be prevented. As a result, breakage of the wires and decrease of the external quantum efficiency caused by a gap along the interface can be prevented.

The inner wall surface of the cup portion of the lead frame 12 may be finished rough to increase the affinity to the encapsulater 20 and the light scattering ratio.

The Inventor experimentally prepared semiconductor light emitting devices as shown in FIGS. 4A and 4B and comparative samples as shown in FIGS. 2A and 2B, and conducted a soldering heating test. More specifically, after immersing the outer lead portions of the light emitting devices into a vessel of molten solder, malfunction by breakage of wires was evaluated. It resulted as follows.

| | | | | | |
|---|---|---|---|---|---|
| Temperature of solder (° C.) | 260 | 280 | 300 | 320 | 340 |
| present invention | 0/10 | 0/10 | 0/10 | 0/10 | 0/10 |
| comparative sample | 0/10 | 1/10 | 2/10 | 3/10 | 5/10 |

In each value, the denominator is the number of tested samples of the semiconductor light emitting device, and the numerator is the number of light emitting devices in which malfunction by breakage of wires occurred. In case of the comparative samples, malfunction by breakage of wires occurred from a temperature around 280° C., and increases with the rise of the solder temperature. In contrast, even under the severe conditions with the temperature of 340° C. and the immersing time of 10 seconds, no malfunction by breakage of wires occurred, and a very excellent heat resistance has been confirmed.

FIGS. 4A and 4B show a construction using an iron or iron-based lead frame 12 having a low thermal conductivity as an example. However, the invention is not limited to it. That is, useless to say, even when using a copper or copper-based lead frame having a relatively high thermal conductivity, the construction shown in FIGS. 4A and 4B promises improvement in heat resistance, and it is still advantageous.

Next explained is a modified version of the semiconductor light emitting device shown in FIGS. 4A and 4B.

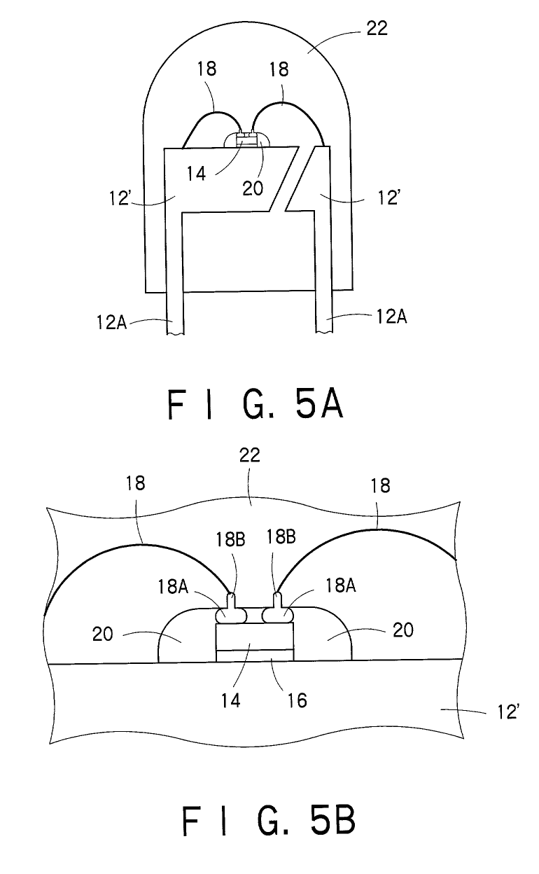

FIGS. 5A and 5B are cross-sectional views schematically showing the modified version of the semiconductor light emitting device shown in FIGS. 4A and 4B. FIG. 5A shows its entirety, and FIG. 5B shows its central part.

Here again, the semiconductor light emitting device has a double-mold structure in which the gallium nitride compound semiconductor light emitting element 14 mounted on a lead frame 12′ made of a material having a lower thermal conductivity than those of copper-based materials is encapsulated by the first encapsulater 20 and the second encapsulater 22. The same components as those of the semiconductor light emitting devices shown in FIGS. 1A through 4B are labeled with common reference numerals, and their detailed explanation is omitted.

A difference of the device shown here from the light emitting device shown in FIGS. 4A and 4B lies in that the lead farms 12′ has no cup portion. That is, in the light emitting device shown in FIGS. 5a and 5B, the head of the lead frame is flat, and the light emitting element 14 is mounted on its flat surface. The light emitting element 14 is surrounded and covered by the first encapsulater 20, and wavelength conversion is done by a fluorescent material contained therein. The first encapsulater 20 is configured so that its surface extends across the thin neck portions 18B of the wires 18. However, the first encapsulater 20 may be configured so that its surface extends across the ball portions 18A. Also in this embodiment, by configuring the ball portions 18A or neck portions 18B of the wires 18 to extend through the surface of the first encapsulater 20, the wires are prevented from breakage even under a shearing stress along the interface between the first encapsulater 20 and the second encapsulater 22.

By configuring the first encapsulater 20 compact around the light emitting element 14, the fluorescent material can be provided with a high density, and the wavelength conversion efficiency thereof and the light condensing efficiency of the second encapsulater 22 can be increased.

Some embodiments of the invention have been explained above, taking specific examples. The invention, however, is not limited to these specific examples. For instance, the specific have examples have been explained as employing a double-mold structure, a triple-mold structure, for example, may be employed, in which a third encapsulater is interposed between the first encapsulater and the second encapsulater.

Additionally, even when the lead frame, light emitting element, wires and encapsulaters may be appropriately changed in configuration from the illustrated configurations, the same effects can be obtained.

While the present invention has been disclosed in terms of the preferred embodiment in order to facilitate better understanding thereof, it should be appreciated that the invention can be embodied in various ways without departing from the principle of the invention. Therefore, the invention should be understood to include all possible embodiments and modification to the shown embodiments which can be embodied without departing from the principle of the invention as set forth in the appended claims.

What is claimed is:

1. A semiconductor light emitting device comprising:
a lead frame; and
a gallium nitride compound semiconductor light emitting element mounted on said lead frame,
said lead frame being made of a material having a thermal conductivity not higher than 100 W/(mK).

2. The semiconductor light emitting device according to claim 1 further comprising:
a first encapsulater provided around said light emitting element to cover it; and
a second encapsulater provided around said first encapsulater to cover it.

3. The semiconductor light emitting device according to claim 2 wherein a coefficient of linear expansion of said first encapsulater lies between that of said second encapsulater and said that of said a gallium nitride compound semiconductor light emitting element.

4. The semiconductor light emitting device according to claim 2 wherein said first encapsulater contains a fluorescent material to absorb light of a first wavelength emitted from said light emitting element and to emit light of a second wavelength different from said first wavelength.

5. The semiconductor light emitting device according to claim 2 herein said first encapsulater is made of an inorganic adhesive.

6. The semiconductor light emitting device according to claim 5 wherein said inorganic adhesive is made of any one selected from the group consisting of alkali metal silicate, phosphate, colloidal silica, silica sol, water glass, Si(OH)ₙ, SiO₂ and TiO₂.

7. The semiconductor light emitting device according to claim 2 wherein said second encapsulater is made of a material having a glass transition temperature not lower than 150° C.

8. The semiconductor light emitting device according to claim 7 wherein said second encapsulater is made of epoxy resin.

9. The semiconductor light emitting device according to claim 1 wherein said lead frame is made of an iron-based material.

10. A semiconductor light emitting device comprising:
a lead frame having an electrode terminal;
a gallium nitride compound semiconductor light emitting element mounted on said lead frame;
a wire connecting said electrode terminal of said lead frame to said light emitting element;
a first encapsulater provided around the light emitting element to cover it; and
a second encapsulater provided around the first encapsulater to cover it,
said wire having a larger diameter at one end portion thereof connected to said light emitting element than the remainder part thereof, and
the boundary between the first encapsulater and the second encapsulater extending across said end portion.

11. The semiconductor light emitting device according to claim 10 wherein said lead frame has a cup portion and said gallium nitride compound semiconductor light emitting element is mounted on the bottom surface of said cup portion.

12. The semiconductor light emitting device according to claim 11 wherein said cup portion of said lead frame defines an inner wall surface which is roughly finished at least in a part thereof.

13. The semiconductor light emitting device according to claim 10 wherein said end portion is a ball portion or a neck portion formed by a bonding of said wire to said light emitting element.

14. The semiconductor light emitting device according to claim 10 wherein said first encapsulater contains a fluorescent material to absorb light of a first wavelength emitted from said light emitting element and to emit light of a second wavelength different from said first wavelength.

15. The semiconductor light emitting device according to claim 10 wherein said first encapsulater is made of an inorganic adhesive.

16. The semiconductor light emitting device according to claim 15 wherein said inorganic adhesive is made of any one selected from the group consisting of alkali metal silicate, phosphate, colloidal silica, silica sol, water glass, Si(OH)ₙ, SiO₂ and TiO₂.

17. The semiconductor light emitting device according to claim 10 wherein said second encapsulater is made of a material having a glass transition temperature not lower than 150° C.

18. The semiconductor light emitting device according to claim 10 wherein said lead frame is made of a material having a thermal conductivity not higher than 100 W/(mK).

19. The semiconductor light emitting device according to claim 18 wherein said lead frame is made of an iron-based material.

20. The semiconductor light emitting device according to claim 19 wherein said lead frame has an outer lead portion applied with solder outer plating.
